(19) United States
(12) Patent Application Publication
(10) Pub. No.: US 2009/0065860 A1
(43) Pub. Date: Mar. 12, 2009

(54) Semiconductor device and method for manufacturing the same

(75) Inventor: Noriaki Mikasa, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/230,931

(22) Filed: Sep. 8, 2008

(30) Foreign Application Priority Data
Sep. 12, 2007 (JP) 2007-236790

(51) Int. Cl. H01L 47/00; H01L 21/336

(52) U.S. Cl. 257/330; 438/270; 257/E47.001; 257/E21.409

(57) ABSTRACT

An exemplary object of the invention is to simultaneously achieve, in a semiconductor device which includes a trench gate structure formed by recessing a portion of a diffusion layer and an inter-diffusion-layer isolation insulating film which are formed on the a semiconductor substrate, good embeddability of the inter-diffusion-layer isolation insulating film and a reduction in channel resistance. In an exemplary embodiment, the diffusion layer which comprises a projecting structure is formed by selectively wet-etching the inter-diffusion-layer isolation insulating film with respect to the diffusion layer in the trench, and an overhanging structure is formed at a projecting portion of the diffusion layer further by selectively epitaxially growing the projecting structure of the diffusion layer.

This application is based upon and claims the benefit of priority from Japanese patent application No. 2007-236790, filed on Sep. 12, 2007, the disclosure of which is incorporated herein in its entirety by reference.

### BACKGROUND OF THE INVENTION

1. Field of the Invention

An exemplary aspect of the invention relates to a semiconductor device which includes a trench gate structure formed by recessing a portion of a diffusion layer and an inter-diffusion-layer isolation insulating film which are formed on the a semiconductor substrate, and a method for manufacturing the same.

2. Description of the Related Art

Semiconductor devices, which include a trench gate structure formed by recessing a portion of a diffusion layer and an inter-diffusion-layer isolation insulating film which are formed on the a semiconductor substrate, have recently been known (Japanese Patent Application Laid-Open Nos. 2003-78033, 2006-173429 and 2006-339476).

Consider here a transistor which includes three diffusion layers and an inter-diffusion layer isolation insulating film formed on a silicon substrate and which includes a trench gate structure formed by recessing a portion of the diffusion layers and the inter-diffusion-layer isolation insulating film. FIG. 27 is a schematic top view showing the configuration of an example of such a transistor. FIGS. 28 and 29 are sectional views of FIG. 27 taken along line A-A and line B-B, respectively. The trench is formed across diffusion layers 1-1, 1-2 and 1-3 (hereinafter collectively referred to “diffusion layers 1”) and inter-diffusion-layer isolation insulating film 2, and amorphous silicon 6 which is embedded in the trench forms the trench gate structure. Inter-gate-layer insulating film 9 is formed to cover the whole surface, and contact 10 is connected to each diffusion layer.

With recent demand for a reduction in circuit area, if diffusion layers 1 are formed to have a conventional width (e.g., LB in FIG. 28 is 100 nm), the width of inter-diffusion-layer isolation insulating film 2 becomes narrow to become difficult to be embedded. Accordingly, void 3 appears in inter-diffusion-layer isolation insulating film 2 (FIGS. 28 and 29).

To cope with this, a method for reducing the width of the diffusion layer is adopted. FIG. 30 is a schematic top view showing the configuration of an example of such a transistor. FIGS. 31 and 32 are sectional views of FIG. 30 taken along line A-A and line B-B, respectively. The reduction in the width of diffusion layers 1 (e.g., LA in FIG. 31 is 50 nm) makes it possible to increase the width of inter-diffusion-layer isolation insulating film 2 and to prevent generation of a void.

However, if the width of the diffusion layer is reduced, the channel width of the transistor is also reduced. Accordingly, channel resistance increases (for example, when LA is 50 nm and LB is 100 nm, the channel resistance increases about twice), and driving current decreases, thus resulting in a reduction in circuit speed.

### SUMMARY OF THE INVENTION

An exemplary object of the invention is to simultaneously achieve, in a semiconductor device which includes a trench gate structure formed by recessing a portion of a diffusion layer and an inter-diffusion-layer isolation insulating film which are formed on the a semiconductor substrate, good embeddability of the inter-diffusion-layer isolation insulating film and a reduction in channel resistance.

An exemplary aspect of the invention is a semiconductor device, which comprises a diffusion layer and an inter-diffusion-layer isolation insulating film isolating the diffusion layer, in which a trench gate structure is formed by recessing a portion of the diffusion layer and the inter-diffusion-layer isolation insulating film:

wherein the diffusion layer comprises an overhanging structure which projects toward the inter-diffusion-layer isolation insulating film in a trench of the trench gate structure.

An exemplary aspect of the invention is a method for manufacturing a semiconductor device, which comprises a diffusion layer and an inter-diffusion-layer isolation insulating film isolating the diffusion layer, in which a trench gate structure is formed by recessing a portion of the diffusion layer and the inter-diffusion-layer isolation insulating film, comprising:

(a) forming a trench formation insulating film which has a pattern of the trench gate structure on the semiconductor substrate on which the diffusion layer and the inter-diffusion-layer isolation insulating film are formed;

(b) patterning the semiconductor substrate on which the diffusion layer and the inter-diffusion-layer isolation insulating film are formed, using the trench formation insulating film as a mask, to form a trench to serve as the trench gate structure;

(c) selectively wet-etching the inter-diffusion-layer isolation insulating film with respect to the diffusion layer in the trench, to form a projecting structure of the diffusion layer;

(d) selectively epitaxially growing the projecting structure of the diffusion layer in the trench, to form an overhanging structure at a projecting portion of the diffusion layer;

(e) removing the trench formation insulating film and forming a gate oxide film on the diffusion layer exposed at a surface;

(f) embedding amorphous silicon or polysilicon in the trench to form the trench gate structure; and

(g) implanting an ion in a region to serve as a source/drain of the diffusion layer to form a source/drain section.

According to an exemplary aspect of the invention, it is possible to simultaneously achieve good embeddability of the inter-diffusion-layer isolation insulating film and a reduction in channel resistance.

### BRIEF DESCRIPTION OF THE DRAWINGS

FIG. 1 is a schematic top view showing a state in which a trench formation insulating film is formed on a semiconductor substrate including the diffusion layer and the inter-diffusion-layer isolation insulating film formed thereon;

FIG. 2 is a sectional view of FIG. 1 taken along line A-A;

FIG. 3 is a sectional view of FIG. 1 taken along line B-B;

FIG. 4 is a schematic top view showing a state in which a trench to serve as a trench gate structure is formed on the semiconductor substrate including the diffusion layer and the inter-diffusion-layer isolation insulating film formed thereon;

FIG. 5 is a sectional view of FIG. 4 taken along line A-A;

FIG. 6 is a sectional view of FIG. 4 taken along line B-B;

FIG. 7 is a sectional view of FIG. 4 taken along line C-C;

FIG. 8 is a sectional view of FIG. 4 taken along line D-D;

FIG. 9 is a schematic top view showing a state in which the projecting structure of the diffusion layer is formed in the trench;

FIG. 10 is a sectional view of FIG. 9 taken along line A-A;

FIG. 11 is a sectional view of FIG. 9 taken along line B-B;

FIG. 12 is a sectional view of FIG. 9 taken along line C-C;

FIG. 13 is a sectional view of FIG. 9 taken along line D-D;

FIG. 14 is a schematic top view showing a state in which the overhanging structure is formed at the projecting diffusion layer in the trench;

FIG. 15 is a sectional view of FIG. 14 taken along line A-A;

FIG. 16 is a sectional view of FIG. 14 taken along line B-B;

FIG. 17 is a sectional view of FIG. 14 taken along line C-C;

FIG. 18 is a sectional view of FIG. 14 taken along line D-D;

FIG. 19 is a schematic top view showing a state in which the trench gate structure is formed;

FIG. 20 is a sectional view of FIG. 19 taken along line A-A;

FIG. 21 is a sectional view of FIG. 19 taken along line B-B;

FIG. 22 is a sectional view of FIG. 19 taken along line C-C;

FIG. 23 is a sectional view of FIG. 19 taken along line D-D;

FIG. 24 is a schematic top view showing the configuration of the transistor in which the diffusion layer includes the overhanging structure projecting toward the inter-diffusion-layer isolation insulating film in the trench;

FIG. 25 is a sectional view of FIG. 24 taken along line A-A;

FIG. 26 is a sectional view of FIG. 24 taken along line B-B;

FIG. 27 is a schematic top view showing the configuration of the transistor which includes a wide diffusion layer;

FIG. 28 is a sectional view of FIG. 27 taken along line A-A;

FIG. 29 is a sectional view of FIG. 27 taken along line B-B;

FIG. 30 is a schematic top view showing the configuration of a transistor which includes a narrow diffusion layer;

FIG. 31 is a sectional view of FIG. 30 taken along line A-A; and

FIG. 32 is a sectional view of FIG. 30 taken along line B-B.

### DETAILED DESCRIPTION OF EXEMPLARY EMBODIMENT

A semiconductor device of an exemplary embodiment includes, on a semiconductor substrate, a diffusion layer and an inter-diffusion-layer isolation insulating film isolating the diffusion layer, in which a trench gate structure is formed by recessing a portion of the diffusion layer and the inter-diffusion-layer isolation insulating film. In a trench of the trench gate structure, the diffusion layer includes an overhanging structure which projects toward the inter-diffusion-layer isolation insulating film. An exemplary embodiment of such a semiconductor device and a method for manufacturing the same will be described below with reference to the drawings.

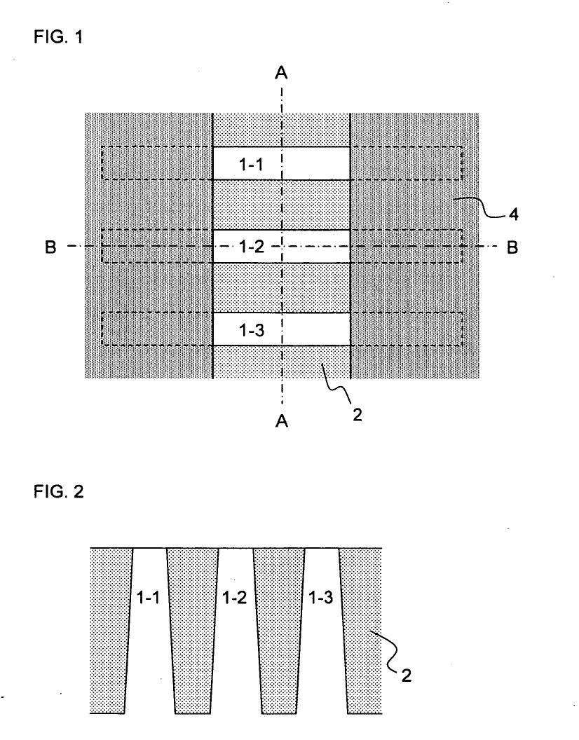

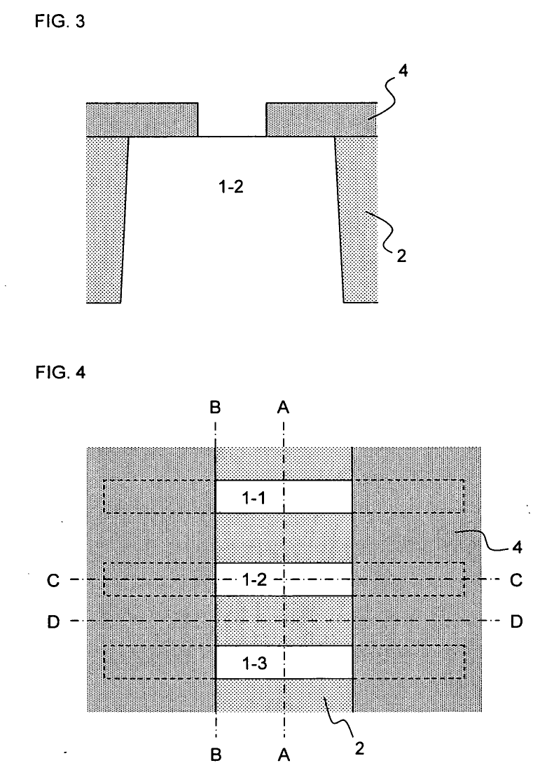

According to an exemplary embodiment, trench formation insulating film 4 which has a pattern of the trench gate structure is first formed on a semiconductor substrate on which diffusion layers 1 and inter-diffusion-layer isolation insulating film 2 are formed (step (a)). FIG. 1 is a schematic top view showing a state after step (a). FIGS. 2 and 3 are sectional views of FIG. 1 taken along line A-A and line B-B, respectively.

The semiconductor substrate including diffusion layers 1 and inter-diffusion-layer isolation insulating film 2 formed thereon can be fabricated in the manner below. First, a mask (e.g., a silicon nitride film) which has a pattern of a region to serve as the diffusion layer is formed on the semiconductor substrate (e.g., a silicon substrate). The semiconductor substrate is patterned using the mask, thereby forming an inter-diffusion-layer isolation trench. By embedding an insulator (e.g., a silicon oxide film) into the inter-diffusion-layer isolation trench, diffusion layers 1 isolated by inter-diffusion-layer isolation insulating film 2 can be formed.

Note that a method of an exemplary embodiment is suitable for a case where the width of diffusion layers 1 is made narrow to prevent generation of a void in inter-diffusion-layer isolation insulating film 2. That is, if the width (LA in FIG. 31) of diffusion layers 1 is not more than 80 nm, an exemplary embodiment is fully effective. Especially, if the width of diffusion layers 1 is not more than 70 nm, an exemplary embodiment produces a profound effect. Examples of the case include a case where LA is 50 nm. Note that even if the width of diffusion layers 1 is more than 80 nm, an exemplary embodiment is also effective when a void is present in inter-diffusion-layer isolation insulating film 2.

The depth of inter-diffusion-layer isolation insulating film 2 is preferably in the range of 200 to 250 nm from the surface of the silicon substrate.

The trench formation insulating film 4 which has the pattern of the trench gate structure can be formed in the manner below. First, trench formation insulating film 4 (e.g., a silicon nitride film) is formed on the semiconductor substrate which includes diffusion layers 1 and inter-diffusion-layer isolation insulating film 2 formed thereon. A photoresist which has the pattern of the trench gate structure is formed on trench formation insulating film 4, and trench formation insulating film 4 is patterned with the pattern of the trench gate structure using the photoresist as a mask.

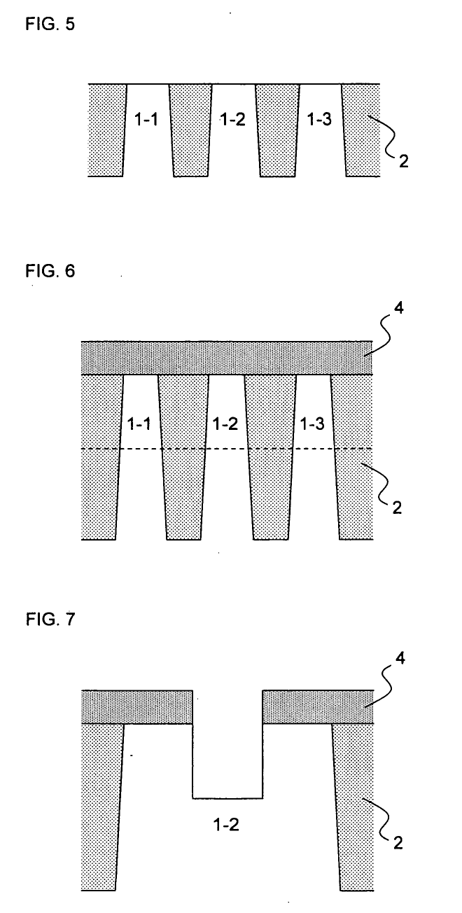

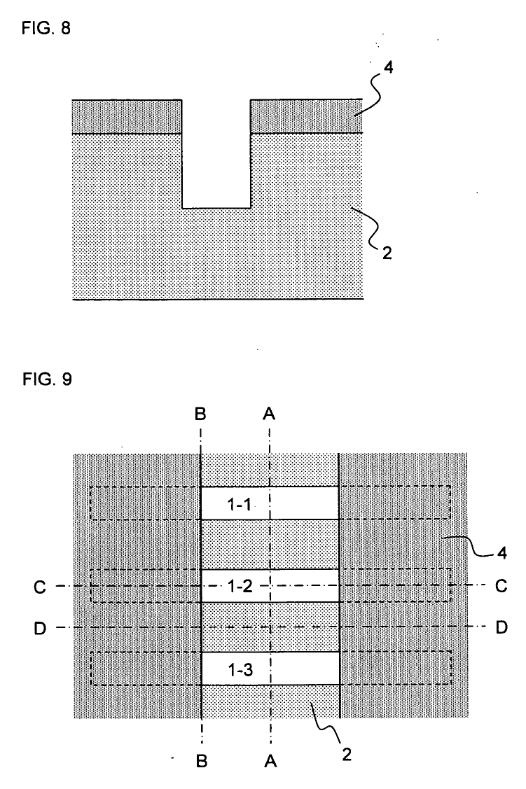

According to an exemplary embodiment, the semiconductor substrate which includes diffusion layers 1 and inter-diffusion-layer isolation insulating film 2 formed thereon is patterned using trench formation insulating film 4 described above as a mask, to form a trench to serve as the trench gate structure (step (b)). FIG. 4 is a schematic top view showing a state after step (b). FIGS. 5 to 8 are sectional views of FIG. 4 taken along line A-A, line B-B, line C-C, and line D-D, respectively. Note that an area above a broken line extending through diffusion layers 1 and inter-diffusion-layer isolation insulating film 2 is exposed at a wall of the trench.

The trench to serve as the trench gate structure can be formed by dry etching. The depth of the trench formed by dry etching is preferably in the range of 100 to 150 nm from the surface of the silicon substrate.

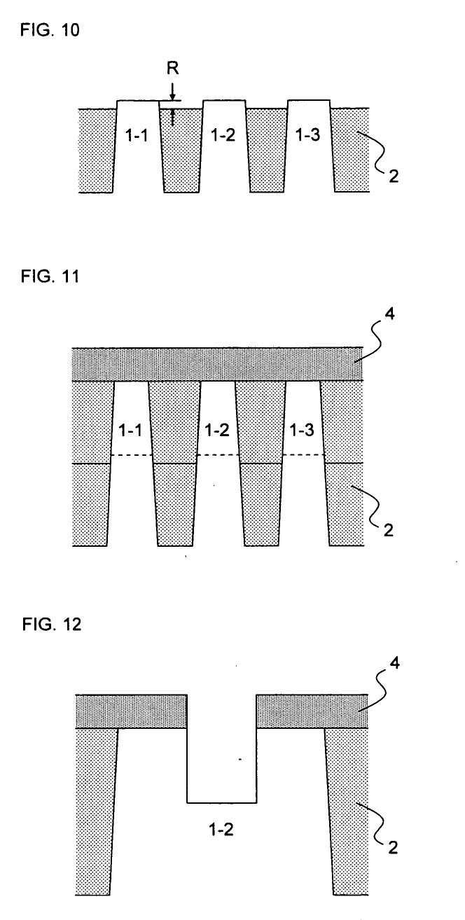

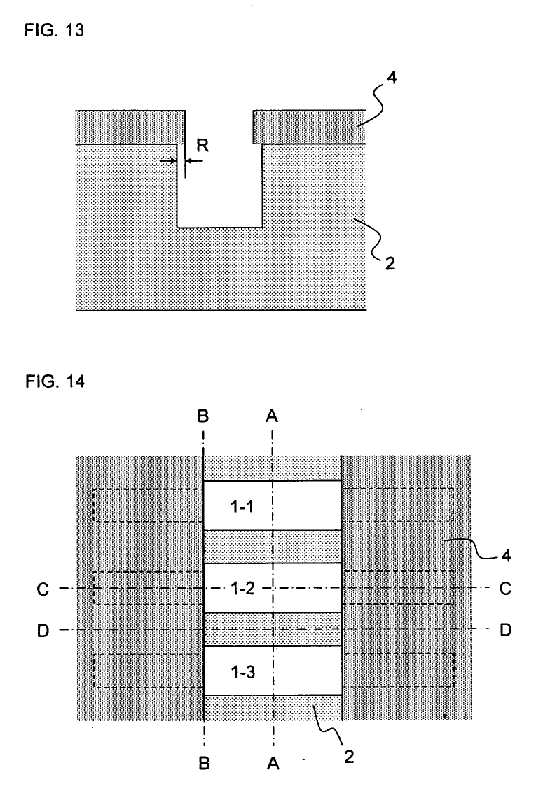

According to an exemplary embodiment, in the formed trench, inter-diffusion-layer isolation insulating film 2 is selectively wet-etched with respect to diffusion layers 1, to form a projecting structure of diffusion layers 1 (step (c)). FIG. 9 is a schematic top view showing a state after step (c). FIGS. 10 to 13 are sectional views of FIG. 9 taken along line A-A, line B-B, line C-C, and line D-D, respectively. Note that, in FIG. 11, an area above a broken line extending through diffusion layers 1 is exposed at the wall of the trench, and an area above a solid line extending through inter-diffusion-layer isolation insulating film 2 is exposed at the wall of the trench and is recessed by thickness R. That is, diffusion layers 1 exposed in the trench project toward inter-diffusion-layer isolation insulating film 2 by thickness R.

Inter-diffusion-layer isolation insulating film 2 is wet-etched on the condition which achieves selectivity with respect to diffusion layers 1. The wet etching is preferably performed on the condition that diffusion layers 1 and trench formation insulating film 4 are little etched. Thickness R, by which inter-diffusion-layer isolation insulating film 2 are etched, is preferably in the range of 5 to 20 nm. For example, R can be set to 10 nm.

The above-described selective wet etching can be performed using a hydrofluoric acid-containing solution. In this case, inter-diffusion-layer isolation insulating film 2 (e.g., silicon oxide film) is etched by 10 nm by means of, e.g., 15 seconds of etching while diffusion layers 1 (silicon) and trench formation insulating film 4 (silicon nitride film) are little etched.

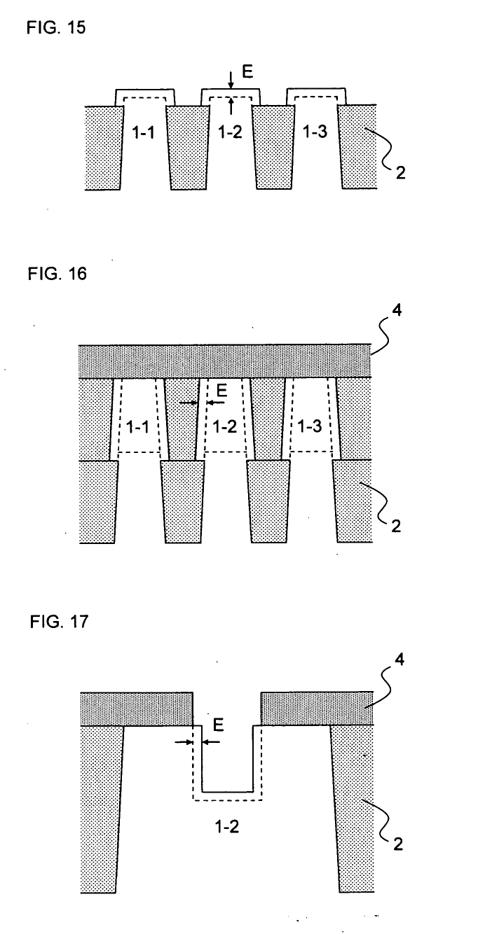

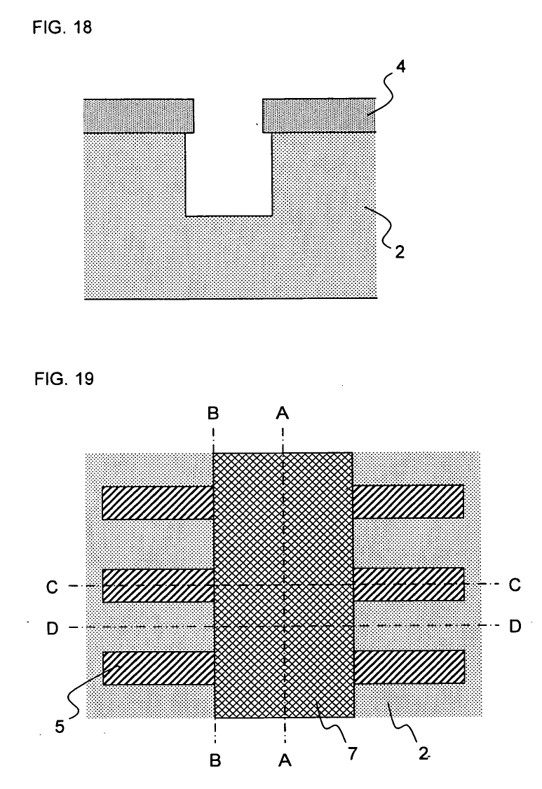

According to an exemplary embodiment, projecting diffusion layers 1 are selectively epitaxially grown, to form an overhanging structure at a projection portion of the diffusion layers 1 (step (d)). FIG. 14 is a schematic top view showing a state after step (d). FIGS. 15 to 18 are sectional views of FIG. 14 taken along line A-A, line B-B, line C-C, and line D-D, respectively. Broken lines in FIGS. 15 to 17 represent a state before the selective epitaxial growth, and the silicon has grown by thickness E. That is, diffusion layer 1 includes the overhanging structure in which diffusion layer 1 exposed in the trench projects toward inter-diffusion-layer isolation insulating film 2 by a thickness (R+E) in a direction in which diffusion layer 1 is spatially open (a direction in which diffusion layer 1 is not in contact with inter-diffusion-layer isolation insulating film 2).

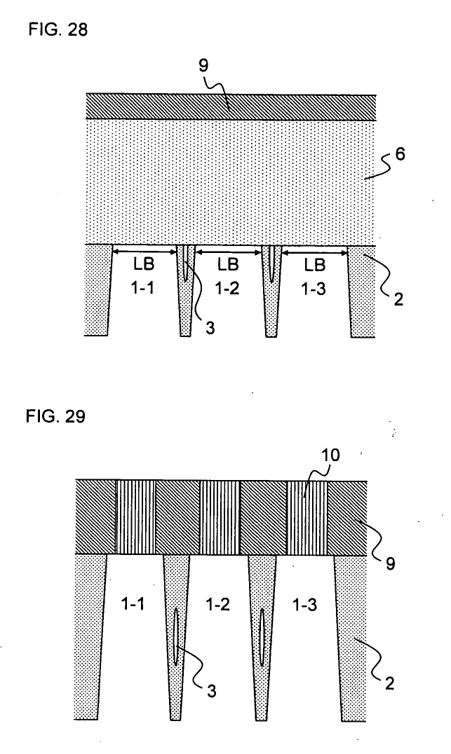

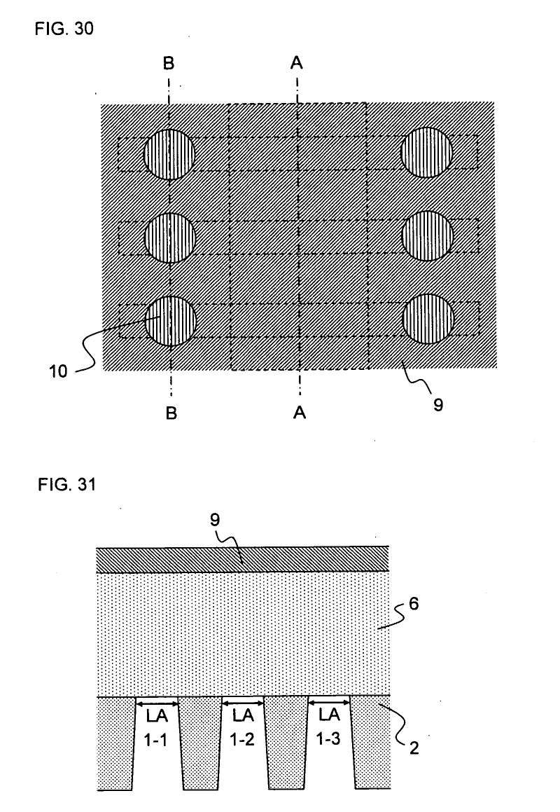

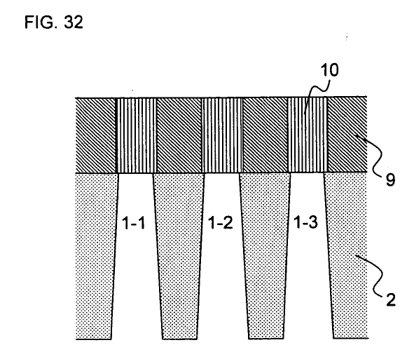

The selective epitaxial growth is performed on the condition that silicon in diffusion layer 1 selectively grows. Thickness E for the selective epitaxial growth is preferably in the range of 10 to 40 nm. It is preferable to set E, using the width (LB in FIG. 28) of diffusion layers 1 before reduction and the width (LA in FIG. 31) of diffusion layers 1 after reduction, such that E is (LB−LA)/2. For example, if LB is 100 nm and LA is 50 nm, E is preferably set to 25 nm.

After step (d), it is preferable to perform channel implantation CH (e.g., boron: 10 keV/1×10¹³ cm⁻²) for threshold voltage adjustment on diffusion layers 1 having the overhanging structure formed by the selective epitaxial growth.

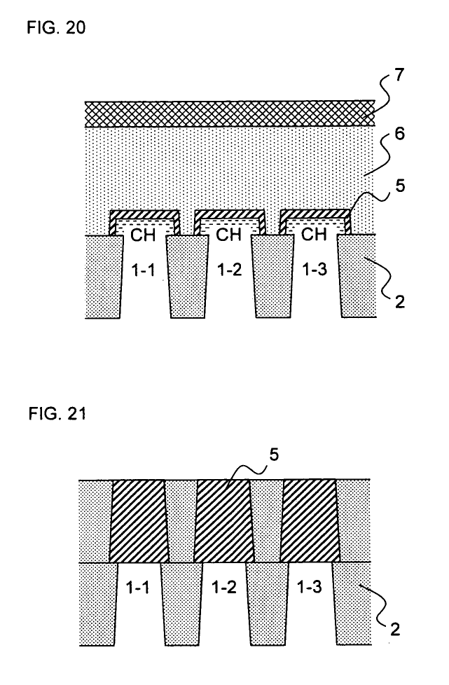

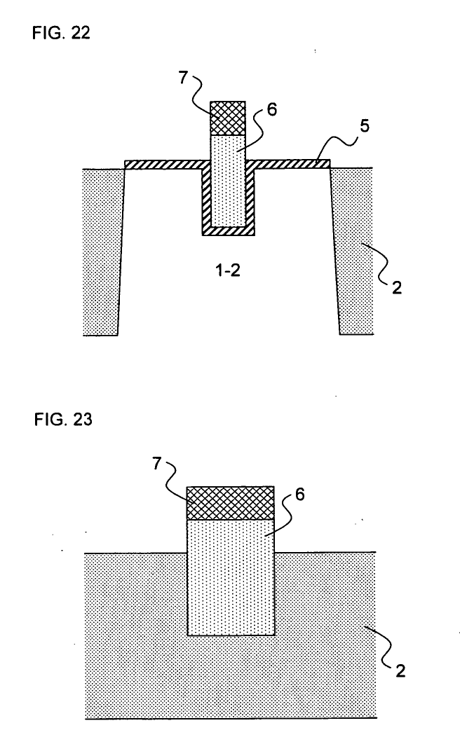

According to an exemplary embodiment, trench formation insulating film 4 is removed, and gate oxide films 5 are formed on diffusion layers 1 exposed at the surface (step (e)). Amorphous silicon 6 (or polysilicon) is embedded in the trench to form the trench gate structure (step (f)). FIG. 19 is a schematic top view showing a state after step (f). FIGS. 20 to 23 are sectional views of FIG. 19 taken along line A-A, line B-B, line C-C, and line D-D, respectively.

Trench formation insulating film 4 can be removed by wet etching with high selectivity with respect to diffusion layers 1 and inter-diffusion-layer isolation insulating film 2. Gate oxide films 5 can be formed by thermal oxidation.

Amorphous silicon 6 is formed to a thickness sufficient to fill the trench. For example, if the width of the trench is 50 nm, amorphous silicon 6 is preferably embedded to a thickness of 100 nm. Next, gate formation insulating film 7 is formed and is dry-etched using a photoresist which has a pattern of the trench gate structure as a mask. Amorphous silicon 6 is dry-etched using gate formation insulating film 7 as a mask to form the trench gate structure.

After step (f), insulating films for gate side walls 8 are formed and are dry-etched to form gate side walls 8.

According to an exemplary embodiment, ions are implanted in a region to serve as a source/drain of diffusion layers 1 to form a source/drain section (step (g)). More specifically,.source/drain implantation SD (e.g., phosphorus: 10 keV/1×10¹³ cm⁻²) is performed through gate oxide films 5 and side walls 8.

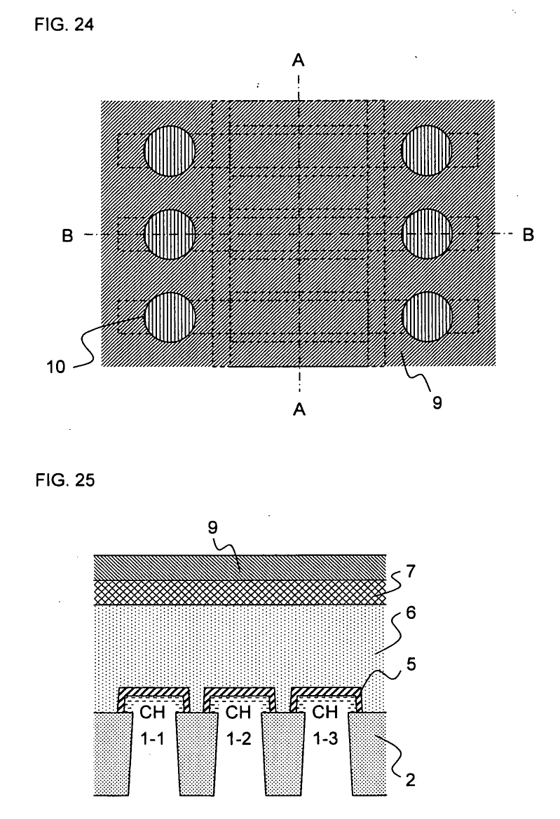

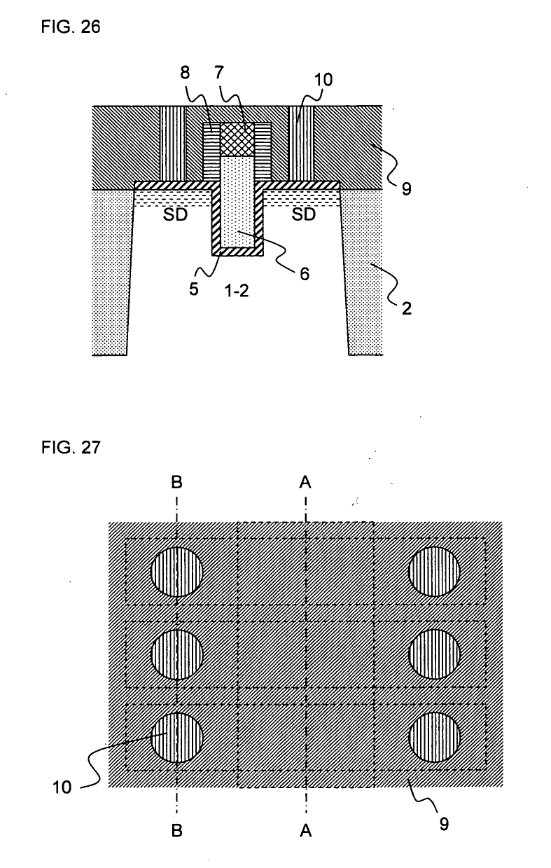

Inter-gate-layer insulating film 9 is formed and planarized by CMP. Inter-gate-layer insulating film 9 is further dry-etched using a photoresist which has a pattern of contacts as a mask, to form source/drain contacts 10 for each transistor on the silicon substrate. FIG. 24 is a schematic top view showing the configuration of a transistor (recess channel transistor) formed in the above-described manner. FIGS. 25 and 26 are sectional views of FIG. 24 taken along line A-A and line B-B, respectively.

As described above, in a semiconductor device which includes, on a semiconductor substrate, a diffusion layer and an inter-diffusion-layer isolation insulating film isolating the diffusion layer, in which a trench gate structure is formed by recessing a portion of the diffusion layer and the inter-diffusion-layer isolation insulating film, only a channel section is subjected to silicon selective epitaxial growth using a processing mask for recessing, and the diffusion layer in a trench of the trench gate structure is formed to include an overhanging structure which projects toward the inter-diffusion-layer isolation insulating film. By making the width of the channel section of the diffusion layer larger than that of a source/drain section, it is possible to simultaneously achieve good embeddability of the inter-diffusion-layer isolation insulating film and a reduction in channel resistance.

The invention is not limited to the Example.

What is claimed is:

1. A semiconductor device, which comprises a diffusion layer and an inter-diffusion-layer isolation insulating film isolating the diffusion layer, in which a trench gate structure is formed by recessing a portion of the diffusion layer and the inter-diffusion-layer isolation insulating film:
wherein the diffusion layer comprises an overhanging structure which projects toward the inter-diffusion-layer isolation insulating film in a trench of the trench gate structure.

2. The semiconductor device according to claim 1, wherein channel implantation is performed on the diffusion layer comprising the overhanging structure.

3. A method for manufacturing a semiconductor device, which comprises a diffusion layer and an inter-diffusion-layer isolation insulating film isolating the diffusion layer, in which a trench gate structure is formed by recessing a portion of the diffusion layer and the inter-diffusion-layer isolation insulating film, comprising:
(a) forming a trench formation insulating film which has a pattern of the trench gate structure on the semiconductor substrate on which the diffusion layer and the inter-diffusion-layer isolation insulating film are formed;
(b) patterning the semiconductor substrate on which the diffusion layer and the inter-diffusion-layer isolation insulating film are formed, using the trench formation insulating film as a mask, to form a trench to serve as the trench gate structure;
(c) selectively wet-etching the inter-diffusion-layer isolation insulating film with respect to the diffusion layer in the trench, to form a projecting structure in the diffusion layer;
(d) selectively epitaxially growing the projecting structure of the diffusion layer in the trench, to form an overhanging structure at a projecting portion of the diffusion layer;
(e) removing the trench formation insulating film and forming a gate oxide film on the diffusion layer exposed at a surface;
(f) embedding amorphous silicon or polysilicon in the trench to form the trench gate structure; and
(g) implanting an ion in a region to serve as a source/drain of the diffusion layer to form a source/drain section.

4. The method for manufacturing the semiconductor device according to claim 3, wherein channel implantation is performed on the diffusion layer having the overhanging structure formed in the step (d).

5. The method for manufacturing the semiconductor device according to claim 3, wherein the wet etching in the step (c) is performed using a hydrofluoric acid-containing solution.

6. The method for manufacturing the semiconductor device according to claim 4, wherein the wet etching in the step (c) is performed using a hydrofluoric acid-containing solution.

7. The method for manufacturing the semiconductor device according to claim 3, wherein the selective epitaxial growth in the step (d) is performed using a dichlorosilane/hydrogen chloride gas.

8. The method for manufacturing the semiconductor device according to claim 4, wherein the selective epitaxial growth in the step (d) is performed using a dichlorosilane/hydrogen chloride gas.

9. The method for manufacturing the semiconductor device according to claim 5, wherein the selective epitaxial growth in the step (d) is performed using a dichlorosilane/hydrogen chloride gas.

10. The method for manufacturing the semiconductor device according to claim 6, wherein the selective epitaxial growth in the step (d) is performed using a dichlorosilane/hydrogen chloride gas.
